(19) United States
(12) Patent Application Publication
(10) Pub. No.: US 2017/0130520 A1
(43) Pub. Date: May 11, 2017

(54) A WINDOW SYSTEM INCLUDING LIGHTING AND SOLAR ENERGY COLLECTION

(71) Applicant: PHILIPS LIGHTING HOLDING B.V., EINDHOVEN (NL)

(72) Inventor: HUGO JOHAN CORNELISSEN, EINDHOVEN (NL)

(21) Appl. No.: 15/322,708

(22) PCT Filed: Jul. 1, 2015
(86) PCT No.: PCT/EP2015/064914

§ 371 Date: Dec. 28, 2016

(30) Foreign Application Priority Data
Jul. 2, 2014 (EP) 14175449.9

(51) Int. Cl. E06B 3/67; F21V 33/00; E06B 7/28; F21V 23/04; H02S 20/26; H01L 31/0468; F21S 9/03; F21V 29/15

(52) U.S. Cl. CPC E06B 3/6715; F21S 9/037; F21V 33/006; F21V 29/15; F21V 23/0464; H02S 20/26; H01L 31/0468; E06B 7/28; F21Y 2105/10

(57) ABSTRACT

A window system has, within the window frame, a solar panel on the outside and a lighting panel on the inside. An efficient, non-transparent, thermal insulation layer can be used between the solar panel and the lighting panel.

### FIELD OF THE INVENTION

The invention relates to a window system including lighting and solar energy collection.

### BACKGROUND OF THE INVENTION

Energy management of houses and buildings is becoming increasingly important with the increase in fuel prices.

Energy is needed for heating, ventilation, air conditioning and lighting but the amount of energy needed should be minimized. There is a desire for buildings that reduce energy consumption and preferably even generate all their required energy or even deliver energy to the power grid. This can be achieved by active measures such as installing photovoltaic systems or wind turbines on the roof.

Also, passive measures like improving thermal insulation of the construction contribute to reach the goal.

It is known that each window in a building constitutes a heat flow leak. Windows and doors may account for approximately one-third of a home's total heat loss. In the winter, energy may leak out and in the summer the heat flow may be reversed and air conditioning is needed.

From an energy saving point of view, windows should be eliminated. On the other hand windows are essential for the well-being of the people working in the building or living in the home. People need visual contact with the world around them.

There is therefore a need for systems that improve the thermal insulation of buildings while maintaining a pleasant interior.

The technologies of photovoltaic energy generation and of solid state light generation have been steadily improving over recent years and have come to a point that new combinations may become feasible.

It is known to integrate solar cells into the frame of a window, and also to include LEDs in the window frame to provide solar powered interior lighting, for example as disclosed in U.S. Pat. No. 8,337,039. However, the window itself remains a significant source of heat loss.

### SUMMARY OF THE INVENTION

The invention is defined by the claims.

According to an aspect of the invention, there is provided a window system, comprising:

a frame;

a panel area within the area defined by the frame,

wherein the panel area comprises:

a solar panel on the outside of the window system;

a lighting panel on the inside of the window system opposite the solar panel; and

a non-transparent thermal insulation layer between the solar panel and the lighting panel.

The invention thus provides a window system, which provides energy generation and light generation to give the appearance of a window, but enables a more thermally efficient construction than a window. Essentially, a virtual window system is provided which can replace either a whole conventional window or a part of a conventional window in a building.

The lighting panel preferably comprises a thin efficient solid-state lighting system. The energy generated by the solar panel can be used by the lighting panel or fed back to the power grid.

In one arrangement, the panel area is filled by the solar panel and the lighting panel. In this way, the complete window is a virtual window.

In another arrangement, the panel area is only partially filled by the solar panel and the lighting panel, and the panel area further comprises a transparent window region.

This enables the size of the thermally inefficient window area to be reduced, to improve thermal efficiency, but at the same time maintaining a large window area (which is partially a real window and partially a virtual window). A real view of the outside is also maintained.

The transparent window region may be at the top or bottom of the panel area for example.

The system preferably further comprises a controller for controlling the lighting panel. The controller may be adapted to set the intensity and/or colour of the light output from the lighting panel in dependence on the ambient lighting characteristics. In this way, the nature of the light provided by the lighting panel can be selected to simulate the natural lighting that would be seen through a conventional window.

The thermal conductivity of the solar panel, thermal insulation and lighting panel together are preferably less than 1 W/m²K. This means the window (or the virtual part of the window) may have a thermal efficiency better than a conventional window, for example approaching or equal to the thermal efficiency of the walls of the building.

The system may form part of a window in a wall of a building, or a skylight in a roof of a building or a door.

Another aspect of the invention provides a lighting method, comprising;

collecting light energy using a solar panel on the outside of a window system which comprises a frame, and a panel area within the area defined by the frame, wherein the solar panel is within the panel area; and

providing lighting using a lighting panel on the inside of the window system opposite the solar panel within the panel area with a non-transparent thermal insulation layer between the solar panel and the lighting panel.

The intensity and/or colour of the lighting from the lighting panel may be set in dependence on the ambient lighting characteristics.

### BRIEF DESCRIPTION OF THE DRAWINGS

Examples of the invention will now be described in detail with reference to the accompanying drawings, in which:

FIG. 1 shows a first example of window system in accordance with the invention;

FIG. 2 shows a building with different types of window system in accordance with the invention; and

FIG. 3 shows a second example of window system in accordance with the invention.

### DETAILED DESCRIPTION OF THE EMBODIMENTS

The invention provides a window system in which, within the window frame, there is a solar panel on the outside and a lighting panel on the inside. An efficient, non-transparent, thermal insulation layer can be used between the solar panel and the lighting panel.

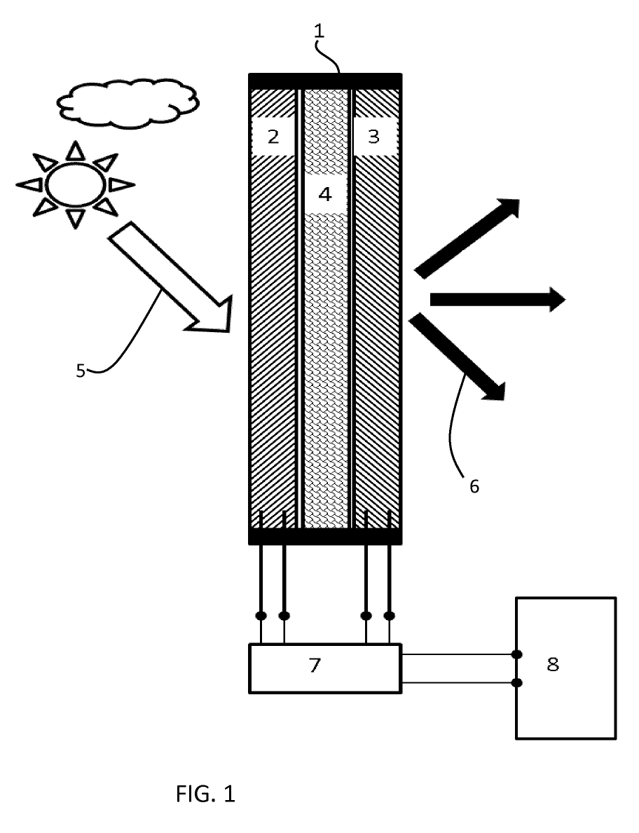

FIG. 1 shows a first example of window system in accordance with the invention,

The window system comprises a frame 1 which defines a panel area within the internal area defined by the frame 1.

The panel area comprises a solar panel 2 on the outside of the window system and a lighting panel 3 on the inside of the window system opposite the solar panel 2. The solar panel collects solar energy 5 and the lighting panel delivers light 6 to the interior space.

A non-transparent thermal insulation layer 4 is provided between the solar panel and the lighting panel.

The invention thus provides a window system, which provides energy generation and light generation to give the appearance of a window, but enables a more thermally efficient construction than a window. Essentially, a virtual window system is provided which can replace either a whole conventional window or a part of a conventional window in a building.

The panel area is essentially the area of the window which is normally glazed. Thus, the frame defines an outer shape, such as a rectangle, but it may include intermediate bars.

The panel area is typically larger than 0.1 m² so that a suitable amount of energy collection is available from the solar panel. The panel area is for example larger than 0.2 m², more than 0.3 m², or more than 0.5 m². The solar panel may for example have a full closed polygonal shape, such as a full square area or rectangular area. The solar panel and lighting panel may have shapes which include the centre of the area defined by the shape of the frame (i.e. the middle of the window system). In other words, the solar panel and lighting panel are located in the middle part of the window rather than only around the edge.

The lighting panel preferably comprises a thin efficient solid-state lighting system. The energy generated by the solar panel can be used by the lighting panel or fed back to the power grid.

The system includes a controller 7 which provides a power management system function. When required, the lighting panel 3 is powered by the controller 7 and generates artificial light 6 which optionally matches the ambient light in color temperature and intensity and dynamics. Otherwise, power is fed back to the power grid or to an energy storage system, as represented generally by unit 8.

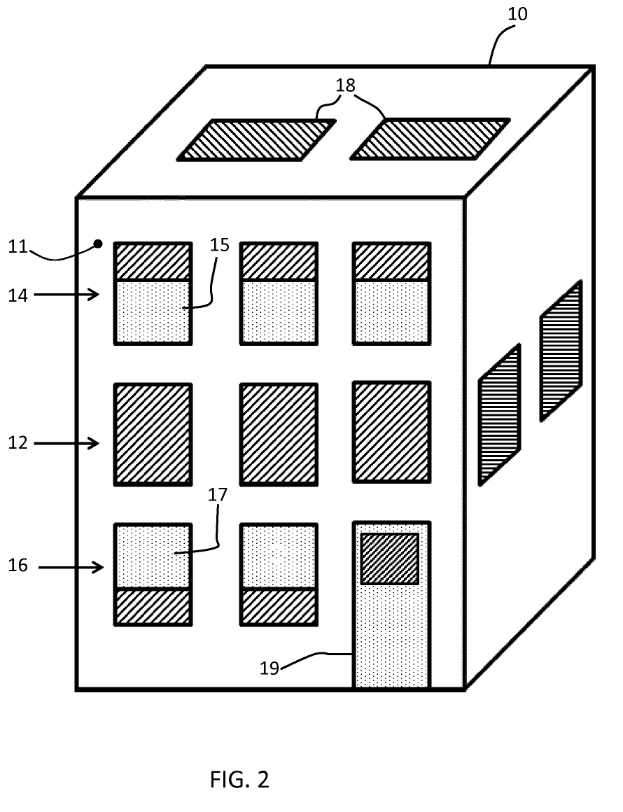

FIG. 2 shows how the window system can be used in a building.

The building 10 has a south facing front wall 11.

The window system can fill the panel area so that the complete window is a virtual window. Alternatively, the panel area may be only partially filled by the solar panel and the lighting panel, and the panel area further comprises a transparent window region. This enables the size of the thermally inefficient window area to be reduced, to improve thermal efficiency, but at the same time maintaining a large window area (which is partially a real window and partially a virtual window). A real view of the outside is also maintained.

FIG. 2 shows a first set 12 of windows (on the middle floor) which are entirely virtual windows. A second set 14 of windows (on the top floor) has a glazed window region 15 at the bottom of the panel area and a virtual window part at the top of the panel area.

A third set 16 of windows (on the ground floor) has a glazed window region 17 at the top of the panel area and a virtual window part at the bottom of the panel area.

The window system can also be used to replace a skylight 18. The front door 19 is also shown with a virtual window.

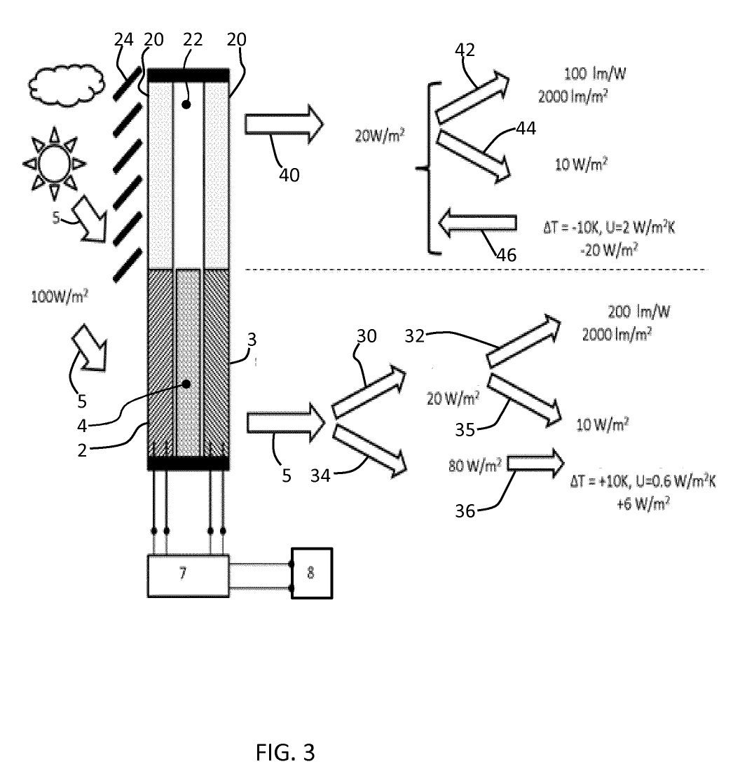

FIG. 3 shows the window system with a glazed section as well as a virtual window section, in more detail.

The glazed section comprises a pair of glass panels 20 and an air (or other gas or vacuum) cavity 22. Blinds 24 are also shown.

The optical, thermal and electrical characteristics will now be discussed.

The solar radiation 5 received by a surface of 1 m² varies during the day and can be in the range of 100-1000 W/m². An example of a possible yearly average is around 100 W/m².

The optical transmission of a double glazed window panel amounts to around 50%. The visible part of the solar radiation corresponds to an illumination intensity of around 100 lm/W. Thus, a window of 1 m² transmits a yearly average of 100 W/m²*50%*100 lm/W=5000 lm/m².

The solar panel and associated electronics converts the incoming solar radiation to electricity with an efficiency of around 20%, so with a yearly radiation average of 100 W/m² represented by arrow 5 it generates 20 W/m² of electricity, as represented by arrow 30.

Only 10 W/m²of energy is needed for the lighting panel to generate a desired 2000 lm/m² (to correspond to the desired amount of visible light for a glazed window as explained below).

In particular, with an efficient lighting system this 10 W/m² can be converted to visible light 32 with an efficiency of 200 lm/W which results in a yield of 10 W/m²*200 lm/W=2000 lm/m².

The other 10 W/m² is used to generate surplus electricity as shown by arrow 35.

The lighting panel generates heat 34 for example with an energy density of 80 W/m²(assuming the total incident 100 W/m² is converted to electrical energy and heat).

The energy savings enabled by using better insulation will now be discussed. The improved insulation can give energy savings in the winter by reducing heat lost from the building, but can also give energy savings in the summer (for a country with a hot summer climate) by reducing heat gained by the building which then needs to be removed by air conditioning for example.

The heat transport through an insulating body is Ψ=U*A*ΔT where U is the thermal conductivity in W/m²K, A is the surface area in m², and ΔT is the temperature difference in K.

With a typical value of U_wall=0.6 W/m²K for a wall and a temperature difference of 10K the heat flow 36 becomes 6 W/m² for a wall. The insulation 4 used within the virtual window (or the non-glazed part of the virtual window) may match the wall thermal insulation of 0.6 W/m²K, and more generally it may be below 1.0 W/m²K.

The glazed window part is shown to provide an irradiation 40 of 20 W/m² after the 50% attenuation by the glass structure and further 60% attenuation by the blinds 24. This comprises energy giving rise to 2000 lm/m² of visible light intensity represented by arrow 42 and 10 W/m² of heat energy 44 (i.e. infrared radiation energy).

With a typical value of U_glass=2 W/m²K for a double glazed window and again a temperature difference of 10K the heat flow 46 becomes 20 W/m² for the glazed window.

As shown in FIG. 3, the energy flow may be out of the building in the winter (as shown by arrow 46) or it may be in to the building (as shown by arrow 36). The simplified analysis above assumes a 10 degree difference in each case, for example an average outdoor temperature of 10 degrees in winter and 30 degrees in summer, with a maintained building temperature of 20 degrees.

Thus, replacing a window by the virtual window system with the equivalent heat conduction of a wall reduces the heat loss (or gain in summer) by 20−6=14 W/m².

If this power density were converted to visible light using the lighting panel, it would correspond to 14 W/m²*200 lm/W=2800 lm/m².

As explained above, a 1 m² window transmits 5000 lm/m² taking into account the 50% transmission of the window glazing. Thus, by replacing a window with a PV system reduces the yearly averaged light input by 5000 lm/m² to the inside of the building (assuming no blinds).

The available electricity in the example above is 20 W/m² which corresponds to 4000 lm/m². When combined with the reduced heat loss which corresponds to 2800 lm/m², the total energy gain expressed in terms of the possible light output is 6800 lm/m². This shows that it is feasible to replace a window or a part of a window by a virtual window system. In particular, the incident visible light intensity can be generated by the solar panel with additional energy generated.

By replacing only part of the window as in some of the examples above, the view to the outside world is maintained. By way of example, it has been calculated that if a window of 1 m×1 m is replaced with a 1m×0.8 m window and a 1 m×0.2 m solar cell, there is a thermal saving of 16 W/m² and 10 W/m² of electricity is generated.

By providing the window system within a frame, the overall appearance can match that of a conventional window, so that even though artificial light is used, a user has the impression of being exposed to natural lighting. For example the thickness of the frame (in a direction normal to the plane of the solar panel and lighting panel) can be thicker than the combined thickness of the solar panel, insulation and lighting panel, again to create window type effect.

As mentioned above, the thermal conductivity of the solar panel, thermal insulation and lighting panel together are preferably less than 1 W/m²K. This means the window (or the virtual part of the window) may have a thermal efficiency better than a conventional window, for example approaching or equal to the thermal efficiency of the walls of the building.

Any known solar panel can be used.

Various different technologies may be used for the lighting panel, such as:

(i) a two dimensional array of phosphor-converted white Light Emitting Diodes (LEDs) enclosed in a white reflective box. One side of the box can be provided with a diffuser through which the light exits the box. The diffuser ensures a spatially uniform light distribution by hiding the bright LEDs. This architecture is known to be highly efficient. The thickness of the system must be of the order of the distance between the LEDs to ensure good uniformity or else additional optics on each LED can be provided to spread the light laterally.

(ii) a light-guide based illumination system similar to those used in backlight systems for Liquid Crystal Displays. Here the light of a one dimensional array of phosphor-converted white LED is injected in a thin light-guiding polymeric sheet and spreads efficiently through total internal reflection. A spatially uniform light distribution can be achieved by a spatially patterned light extraction pattern consisting for instance of small painted white dots. This architecture is known to be efficient and very thin, of the order of a few millimetres only.

(iii) a lighting system based on blue LEDs that generates a large-area, uniform blue light source where just before exiting the system part of the blue light is converted to longer wavelengths in a (remote) phosphor layer, optionally organic phosphor or quantum dot phosphor. This is known to be more efficient than placing the phosphor inside the LED package.

The system makes use of a controller for controlling the light output of the lighting panel. Components that may be employed for the controller include, but are not limited to, conventional microprocessors, application specific integrated circuits (ASICs), and field-programmable gate arrays (FPGAs).

In various implementations, a processor or controller may be associated with one or more storage media such as volatile and non-volatile computer memory such as RAM, PROM, EPROM, and EEPROM. The storage media may be encoded with one or more programs that, when executed on one or more processors and/or controllers, perform at the required functions. Various storage media may be fixed within a processor or controller or may be transportable, such that the one or more programs stored thereon can be loaded into a processor or controller.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage. Any reference signs in the claims should not be construed as limiting the scope.

1. A window system, comprising:
a frame;
a panel area within the area defined by the frame,
wherein the panel area comprises:
a solar panel on the outside of the window system;
a lighting panel on the inside of the window system opposite the solar panel; and
a non-transparent thermal insulation layer between the solar panel and the lighting panel,
wherein the thermal conductivity of the solar panel, thermal insulation and lighting panel together is less than 1 W/m²K.

2. A system as claimed in claim 1, wherein the panel area is filled by the solar panel and the lighting panel.

3. A system as claimed in claim 1, wherein the panel area is only partially filled by the solar panel and the lighting panel, and the panel area further comprises a transparent window region.

4. A system as claimed in claim 3, wherein the transparent window region is at the top of the panel area.

5. A system as claimed in claim 3, wherein the transparent window region is at the bottom of the panel area.

6. A system as claimed in claim 1, further comprising a controller for controlling the lighting panel.

7. A system as claimed in claim 6, wherein the controller is adapted to set the intensity and/or colour of the light output from the lighting panel in dependence on the ambient lighting characteristics.

8. (canceled)

9. A system as claimed in claim 1, wherein the lighting panel comprises a solid state lighting panel.

10. A system as claimed in claim 1 forming part of:
a window in a wall of a building;
a skylight in a roof of a building; or
a door.

11. A lighting method, comprising;
collecting light energy using a solar panel on the outside of a window system which comprises a frame and a panel area within the area defined by the frame, wherein the solar panel is within the panel area; and
providing lighting using a lighting panel on the inside of the window system opposite the solar panel within the panel area with a non-transparent thermal insulation layer between the solar panel and the lighting panel, wherein the thermal conductivity of the solar panel, thermal insulation and lighting panel together is less than 1 W/m²K.

12. A method as claimed in claim 11, comprising setting the intensity and/or colour of the lighting from the lighting panel in dependence on the ambient lighting characteristics.
